(19) United States
(12) Patent Application Publication
(10) Pub. No.: US 2011/0239941 A1
(43) Pub. Date: Oct. 6, 2011

(54) EVAPORATION APPARATUS

(75) Inventors: Yoshiyuki Nakagawa, Chiba-shi (JP); Masanori Yoshida, Chiba-shi (JP); Masamichi Masuda, Mobara-shi (JP); Junji Ohyama, Yokohama-shi (JP); Akio Koganei, Ichikawa-shi (JP); Naotoshi Miyamachi, Mobara-shi (JP); Hirohito Yamaguchi, Mobara-shi (JP); Tetsuya Karaki, Kawasaki-shi (JP); Nobutaka Ukigaya, Mobara-shi (JP); Toshiaki Yoshikawa, Yokohama-shi (JP)

(73) Assignee: CANON KABUSHIKI KAISHA, Tokyo (JP)

(21) Appl. No.: 13/074,124

(22) Filed: Mar. 29, 2011

(30) Foreign Application Priority Data
Apr. 5, 2010 (JP) 2010-086893
Mar. 10, 2011 (JP) 2011-052591

(51) Int. Cl. C23C 16/448; C23C 14/34

(52) U.S. Cl. 118/726; 204/298.11

(57) ABSTRACT

Provided is an evaporation apparatus which reduces deformation of a mask, improves adhesion between a substrate and an evaporation mask, and improves accuracy of dividing a region on which a film is to be formed and a region on which the film is not to be formed. The evaporation apparatus includes a pressing mechanism for pressing a film forming substrate disposed on an evaporation mask including a magnetic material against the evaporation mask. The pressing mechanism includes a magnet for attracting the mask toward at least a corner portion of the film forming substrate.

### BACKGROUND OF THE INVENTION

1. Field of the Invention

The present invention relates to an evaporation apparatus, and more particularly, to an evaporation apparatus suitable for evaporation using a mask.

2. Description of the Related Art

When an organic compound layer or an electrode which forms an organic electroluminescent (EL) element is formed in a specific pattern by a vacuum film forming method such as sputtering, evaporation, or the like, as a specific method, there is widely and generally adopted patterning using a shadow mask having an opening which corresponds to a region on which a film is to be formed.

In recent years, as higher and higher definition elements are required, a mask for vacuum evaporation with which a high definition pattern may be formed with high accuracy becomes necessary.

In a vacuum evaporation apparatus, after a substrate on which a thin film is to be formed (film forming substrate) is overlaid on and aligned with a mask, a film is formed with the substrate and the mask being fixed in an opposing state to an evaporation source or a sputtering target.

Here, when the film is formed, in order to prevent occurrence of a gap between the mask and the substrate, the substrate and the mask are brought into intimate contact with each other in the evaporation apparatus by applying pressing force or the like. For example, as described in Japanese Patent Application Laid-Open No. 2005-158571, a method is proposed in which the adhesion between the substrate and the evaporation mask is enhanced by physically pressing the substrate against the evaporation mask with a weight, a plunger pin, or the like. By enhancing the adhesion between the substrate and the mask in this way, a material is prevented from going around the mask to reach the backside thereof, and a region on which the film is to be formed and a region on which the film is not to be formed are accurately divided.

However, when the size of the substrate is large, due to dead weight of the substrate and the evaporation mask, distortion caused in a center portion of the evaporation mask becomes conspicuous. Even if pressing force is applied to the whole substrate, the adhesion between the substrate and the evaporation mask is reduced at edge portions of the substrate, in particular, in the four corners (corner portions) of the substrate.

As a result, the accuracy of dividing a region on which the film is to be formed and a region on which the film is not to be formed is reduced.

Further, when force is applied uniformly to the substrate from above according to the method disclosed in Japanese Patent Application Laid-Open No. 2005-158571, loads applied to the substrate and to the evaporation mask become large to deform the substrate and the evaporation mask. As a result, borders between a region on which the film is to be formed and a region on which the film is not to be formed are displaced from desired positions to reduce the accuracy of dividing the region on which the film is to be formed and the region on which the film is not to be formed.

### SUMMARY OF THE INVENTION

The present invention has been made to solve the above-mentioned problem, and an object of the present invention is to provide an evaporation apparatus which reduces deformation of a mask, improves adhesion between a substrate and an evaporation mask, and improves accuracy of dividing a region on which a film is to be formed and a region on which the film is not to be formed.

According to the present invention, an evaporation apparatus includes a unit for holding an evaporation mask including a metal foil including a ferromagnetic material and a mask frame for fixing the metal foil and a pressing mechanism for pressing the evaporation mask including the magnetic material against a film forming substrate. The pressing mechanism includes, at least in four corner portions of the film forming substrate, magnets for attracting the evaporation mask toward the film forming substrate. The evaporation apparatus may further include a pressing body for pressing against the mask a periphery of the film forming substrate.

According to the present invention, there may be provided an evaporation apparatus which reduces deformation of an evaporation mask, improves the adhesion between a film forming substrate and the evaporation mask, and improves the accuracy of dividing a region on which a film is to be formed and a region on which the film is not to be formed.

Further features of the present invention will become apparent from the following description of exemplary embodiments with reference to the attached drawings.

### BRIEF DESCRIPTION OF THE DRAWINGS

FIG. 1 is a schematic sectional view illustrating an evaporation apparatus according to an embodiment of the present invention.

FIGS. 2A and 2B are schematic views illustrating a preferred positional relationship of balls and magnets with respect to an evaporation mask and a substrate.

FIGS. 3A, 3B and 3C are sectional views schematically illustrating action of the present invention.

FIG. 4 is a schematic sectional view illustrating an evaporation apparatus used in Example 1.

FIG. 5 is an enlarged schematic sectional view illustrating openings in an evaporation mask of the evaporation apparatus.

FIGS. 6A and 6B are schematic views illustrating a second exemplary arrangement of the magnets and the pressing bodies of the pressing mechanism provided in the evaporation apparatus according to the present invention.

### DESCRIPTION OF THE EMBODIMENTS

An evaporation apparatus according to the present invention includes at least an evaporation source, a mechanism for holding a film forming substrate disposed on an evaporation mask including a magnetic material, and a pressing mechanism for pressing the film forming substrate against the evaporation mask. Here, the evaporation mask is a member including metal foil which contains a ferromagnetic material and a mask frame for fixing the metal foil thereto. The pressing mechanism is a member located above the evaporation mask, and magnets are arranged at positions above corner portions of the film forming substrate, the substrate being mounted on the evaporation mask. According to the present invention, it is preferred that the pressing mechanism include, in addition to the above-mentioned magnets, a pressing body for pressing the above-mentioned film forming substrate against the evaporation mask at the periphery of the film forming substrate and above the mask frame.

An embodiment of the evaporation apparatus according to the present invention is described in the following with reference to the attached drawings. Note that, appropriate design changes which fall within the scope of the present invention may be made and the present invention is by no means limited to the embodiment described below.

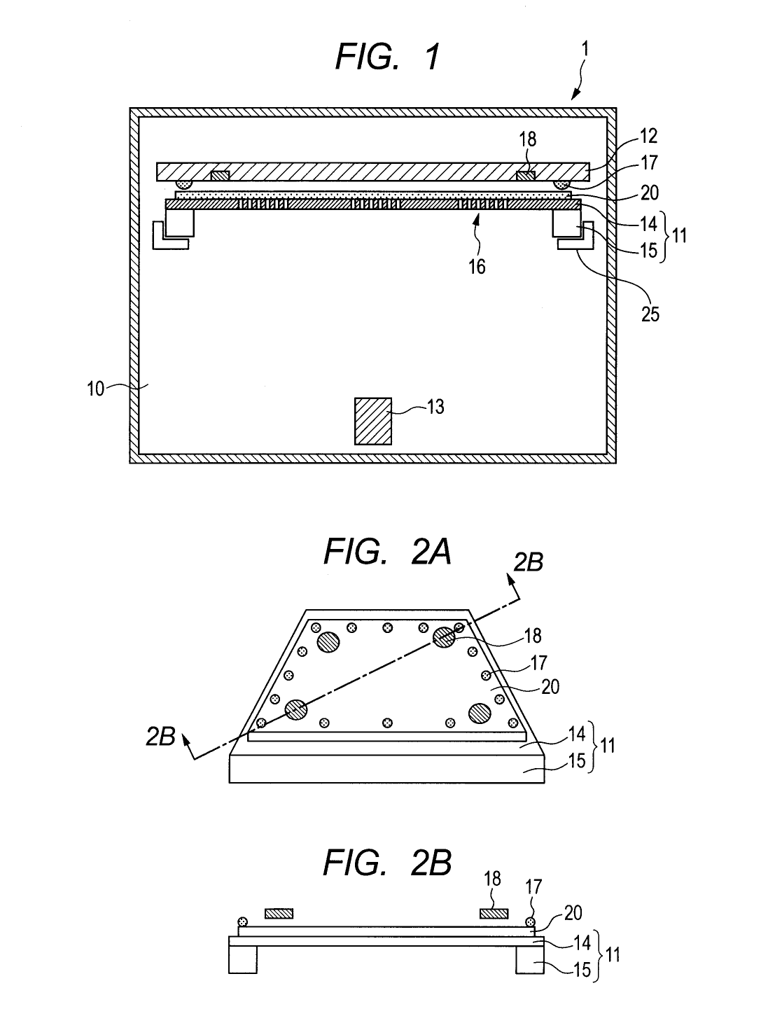

FIG. 1 is a schematic sectional view illustrating the evaporation apparatus according to an embodiment of the present invention. An evaporation apparatus 1 illustrated in FIG. 1 includes an evaporation mask 11, a mechanism 25 for holding the evaporation mask 11 having a film forming substrate disposed thereon, a pressing mechanism 12 (hereinafter also referred to as touch plate), and an evaporation source 13 which are provided in an evaporation chamber 10. In the evaporation apparatus 1 illustrated in FIG. 1, a film forming substrate 20 (hereinafter also simply referred to as “substrate”) is mounted on the evaporation mask 11. Further, the evaporation apparatus 1 illustrated in FIG. 1 is, for example, an apparatus used in manufacturing an organic electroluminescent device.

Members forming the evaporation apparatus 1 illustrated in FIG. 1 are now described in the following.

The evaporation chamber 10 is connected to a vacuum evacuation system (not shown). When vacuum evaporation is actually carried out, pressure in the evaporation chamber 10 is adjusted to be in a range of 1.0×10⁻⁴ Pa to 1.0×10⁻⁶ Pa by the vacuum evacuation system.

The evaporation mask 11 is a member including metal foil 14 and a mask frame 15. The metal foil 14 is a thin-film-like member which contains a ferromagnetic material. The metal foil 14 has openings 16 therein which are patterned in a predetermined shape so that an evaporation material is deposited only at desired positions on the substrate 20. The mask frame 15 is a member made of a rigid material, for fixing the metal foil 14 thereto.

The pressing mechanism (touch plate) 12 includes balls 17 and magnets 18. Here, the balls 17 are pressing bodies for pressing side portions and corner portions of the substrate 20 to be mounted on the evaporation mask 11. The magnets 18 are members for attracting the metal foil 14 containing a ferromagnetic material together with the substrate 20 toward the touch plate 12. According to the present invention, the magnets 18 as members for ensuring adhesion between the substrate 20 and the metal foil 14 are essential. However, from the viewpoint of ensuring the adhesion between the substrate 20 and the metal foil 14, it is preferred that the magnets 18 be used in combination with the pressing bodies 17. Note that, preferred places at which the pressing bodies 17 and magnets 18 are provided are to be described below.

The evaporation source 13 includes at least an evaporation material storage portion (not shown) for storing the evaporation material and heating means (not shown) for heating the evaporation material.

FIGS. 2A and 2B are schematic views illustrating a preferred positional relationship of the pressing bodies and the magnets with respect to the evaporation mask and the substrate. FIG. 2A is a perspective view and FIG. 2B is a sectional view taken along the line 2B-2B of FIG. 2A.

As illustrated in FIG. 2A, the pressing bodies 17 are provided over the side portions and the corner portions of the substrate 20 supported by the mask frame 15. This causes the side portions and the corner portions of the substrate 20 to be pressed by the pressing bodies 17 on the mask frame 15 and to be fixed on the evaporation mask 11 (metal foil 14). Note that, according to the present invention, as the pressing bodies, members having protrusions such as plunger pins may be provided instead of the balls illustrated in FIG. 2A. Further, the method of pressing the substrate by the pressing bodies 17 is not specifically limited in the present invention, and adjustment by a combination of balls or pins with springs is also possible.

The magnets 18 are provided at positions which correspond to the vicinity of at least four corner portions of the substrate 20. Note that, when the magnets 18 are provided, for example, one magnet may be provided only at each position which corresponds to the vicinity of a corner portion of the substrate 20 as illustrated in FIG. 2A, but the present invention is not limited thereto. Multiple magnets may be provided at the each position which corresponds to the vicinity of a corner portion, or, as illustrated in FIG. 6A, multiple magnets may be additionally provided at each position which corresponds to an edge of the substrate. In either case, the magnets are provided above the metal foil along the inner side of the mask frame. Further, magnetic force strength and shape of the magnets 18 provided at positions which correspond to the vicinity of the corner portions and to the periphery of the substrate according to the present invention are not specifically limited. Note that, when the magnets 18 are arranged in the vicinity of the openings 16 in the metal foil 14, the openings 16 may be deformed when the metal foil 14 is attracted by the magnets 18. Therefore, it is preferred that the magnets 18 be provided away from the openings 16 in the metal foil 14.

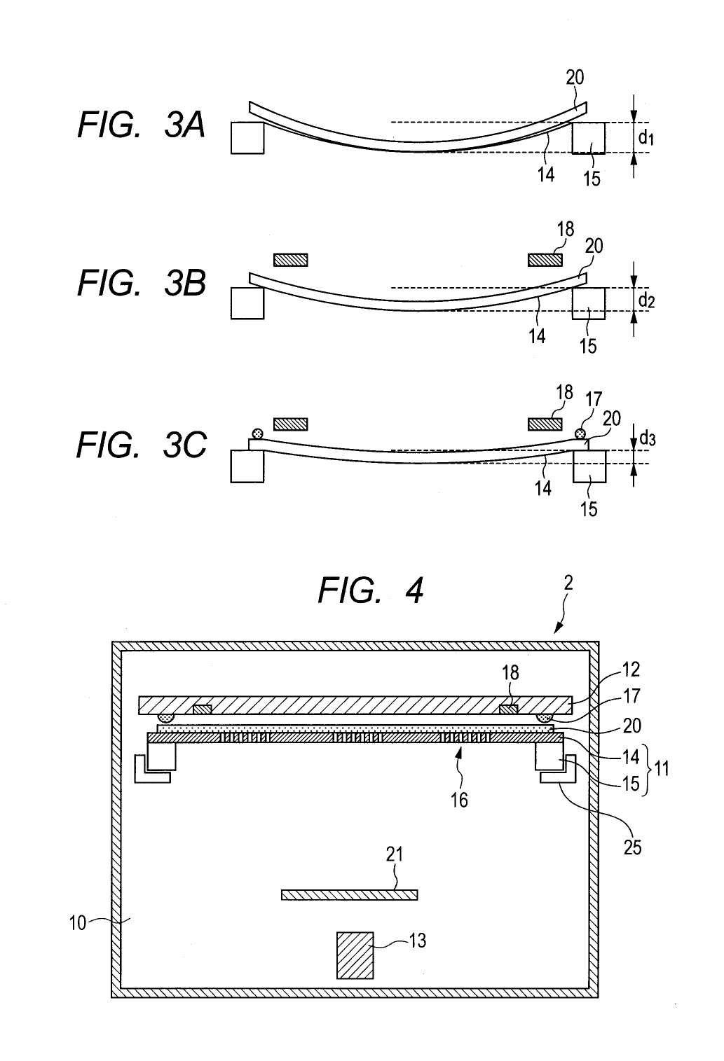

FIGS. 3A to 3C are sectional views schematically illustrating action of the present invention. When a thin film is formed on the substrate in the evaporation apparatus according to the present invention, first, the substrate 20 is mounted on the evaporation mask (FIG. 3A). At this time, a center portion of the substrate 20 is greatly distorted downward due to dead weight (amount of the distortion: d₁), and at the same time, a gap is caused between an edge portion of the substrate 20 and the metal foil 14. The gap is large along the sides of the substrate 20 and becomes the largest in the corner portions of the substrate 20.

Here, when the magnets 18 are brought close to the substrate 20 above the substrate 20, the magnetic force of the magnets 18 lifts the metal foil 14 up (FIG. 3B). The lift of the metal foil 14 brings the metal foil 14 closer to the substrate 20, and thus, the adhesion between the metal foil 14 and the substrate 20 is improved. Further, the lift of the metal foil 14 applies upward force to the substrate 20. This reduces the distortion of the substrate due to the dead weight. Here, let the amount of the distortion of the substrate when the magnets 18 are brought close thereto be d₂, then a relationship of d₁>d₂ is satisfied.

Next, the edge portions of the substrate 20, specifically, the side portions and the corner portions are pressed by the balls 17 as the pressing bodies on the mask frame (FIG. 3C). At this time, by the principle of leverage, the center portion of the substrate 20 is lifted up by an amount according to the pressing of the edge portions of the substrate 20, and thus, the amount of the distortion is further reduced. Here, let the amount of the distortion of the substrate after the substrate is pressed be d₃, then a relationship of d₂>d₃ is satisfied. Note that, when the substrate 20 is lifted up by being pressed by the balls 17, the metal foil 14 is attracted upward by the magnetic force of the magnets 18, and thus, the adhesion between the substrate 20 and the metal foil 14 remains ensured.

In this way, the adhesion between the substrate 20 and the metal foil 14 is improved by the pressing mechanism including the magnets 18 and the pressing bodies (balls) 17, and thus, a region on which the film is to be formed and a region on which the film is not to be formed are accurately divided in the evaporation. Further, in the evaporation apparatus according to the present invention, distortion of the evaporation mask 11 itself may be reduced, and thus, service life of the evaporation mask may be increased.

Note that, the substrate 20 may be brought into the evaporation chamber and may be brought out of the evaporation chamber by a transfer apparatus (not shown). Further, using the transfer apparatus, the evaporation operation may be carried out successively with regard to multiple substrates 20.

### Example 1

FIG. 4 is a schematic sectional view illustrating an evaporation apparatus used in this example. An evaporation apparatus 2 illustrated in FIG. 4 has the same structure as that of the evaporation apparatus illustrated in FIG. 1 except that a shutter 21 is provided between the evaporation mask 11 and the evaporation source 13 in the evaporation apparatus 2 illustrated in FIG. 4. In the evaporation apparatus 2 illustrated in FIG. 4, the shutter 21 is a member provided for controlling an amount of evaporation. More specifically, the shutter 21 has an opening and closing mechanism (not shown) which opens at the start of the evaporation and closes when an intended amount of an evaporation material is deposited on the substrate.

Here, the evaporation apparatus illustrated in FIG. 4 was used to carry out evaporation. Note that, when the evaporation was carried out, the pressure in the evaporation chamber 10 was adjusted to be in a range of about 1.0×10⁻⁴ Pa to 1.0×10⁻⁶ Pa.

Further, in this example, in the evaporation mask 11 which was used, the material of the metal foil 14 was invar (alloy containing Fe and Ni) and the thickness of the metal foil 14 was 50 μm. Further, in this example, the size of the substrate 20 was 360 mm×470 mm×0.5 mm, and the mask frame 15 was a rectangular frame having an inner size of 340 mm×450 mm, an outer size of 460 mm×570 mm, and a thickness of 50 mm.

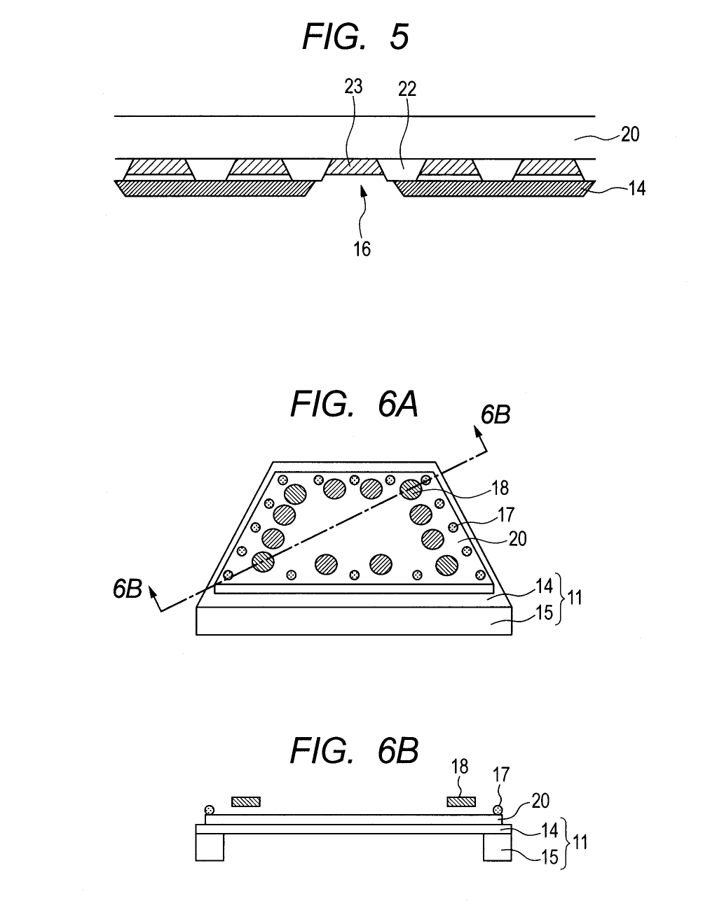

FIG. 5 is an enlarged schematic sectional view illustrating the openings in the evaporation mask of the evaporation apparatus illustrated in FIG. 4. When a display device such as an organic light-emitting device is actually manufactured, an electrode layer (not shown) and an organic EL layer 23 are formed on the substrate 20 on which banks 22 for dividing organic light-emitting elements forming the device are provided in advance. Here, when RGB pixels are required to be formed at desired positions, the substrate 20 is appropriately moved to make an adjustment so that regions on which desired pixels are to be formed are aligned with the corresponding openings 16 in the mask.

As illustrated in FIG. 2A, the balls 17 of the touch plate are provided over the side portions and the corner portions of the substrate. The magnets 18 of the touch plate are provided only above the corner portions of the substrate.

In this example, as the balls 17, sixteen balls each having weight of 40 g were arranged at positions which are 5 mm inside from the edge portions of the substrate at regular intervals along the sides. As the magnets 18, four ferrite magnet of about 0.1 T having a diameter of 15 mm and a thickness of 8 mm were arranged at positions which are 20 mm inside from the corners of the substrate and which are on diagonal lines of the substrate.

Note that, the touch plate 12 having the balls 17 and the magnets 18 may freely adjust the distance therefrom to the substrate 20 by an up and down mechanism (not shown). In this example, the distance between the magnets 18 and the substrate 20 was set to 5 mm and the balls 17 are in a state of pressing the substrate 20. Here, the state of adhesion between the substrate 20 and the evaporation mask 11 (metal foil 14) was measured. It was confirmed that substantially the whole surface of the substrate 20 was in intimate contact with the evaporation mask 11.

Further, in the evaporation apparatus of this example, an amount of the distortion of the substrate 20 and the evaporation mask 11 in the vicinity of the center of the substrate 20 was about 200 μm. The amount of the distortion was reduced by about 100 μm compared with a case where pressing by the balls 17 was not carried out and by about 200 μm compared with a case where the magnets 18 were not arranged.

As described above, the evaporation apparatus according to the present invention reduced distortion of the mask, improved the adhesion between the substrate and the evaporation mask, and improved the accuracy of dividing a region on which the film is to be formed and a region on which the film is not to be formed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2010-086893, filed Apr. 5, 2010, and 2011-052591, filed Mar. 10, 2011 which are hereby incorporated by reference herein in their entirety.

What is claimed is:

1. An evaporation apparatus comprising:
a mechanism for holding an evaporation mask comprising a metal foil including a ferromagnetic material and a mask frame for fixing the metal foil; and
a pressing mechanism for pressing a film forming substrate disposed on the evaporation mask against the evaporation mask,
wherein the pressing mechanism comprises a magnet at least at a position which corresponds to a corner portion of the film forming substrate.

2. The evaporation apparatus according to claim 1, wherein the pressing mechanism further comprises a pressing body for pressing the film forming substrate against the evaporation mask at a position which corresponds to a periphery of the film forming substrate disposed on the evaporation mask and above the mask frame.
